(19) United States
(12) Patent Application Publication
(10) Pub. No.: US 2007/0138001 A1
(43) Pub. Date: Jun. 21, 2007

(54) METHOD OF FORMING AN INDUCTOR ON A SEMICONDUCTOR SUBSTRATE

(76) Inventors: Teng-Yuan Ko, Hsin-Chu Hsien (TW); Ying-Zhan Chang, I-Lan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/306,189

(22) Filed: Dec. 19, 2005

(51) Int. Cl. C23C 14/00

(52) U.S. Cl. 204/192.15

(57) ABSTRACT

A method of forming an aluminum-copper alloy film capable of preventing copper precipitation includes: (a) loading a wafer into a PVD tool comprising a vacuum transfer chamber that couples to a cool down chamber, an aluminum-copper sputter deposition process chamber and an anti-reflection coating process chamber; (b) sputter-depositing a first layer of aluminum-copper alloy onto the wafer in the aluminum-copper sputter deposition process chamber to a first thickness; (c) inter-cooling the wafer and the first layer of aluminum-copper alloy in the cool down chamber; (d) sputter-depositing a second layer of aluminum-copper alloy onto the cooled down first layer of aluminum-copper alloy in the aluminum-copper sputter deposition process chamber to a second thickness; and (e) repeating steps (b) to (d) until a third thickness of the aluminum-copper alloy is reached.

### BACKGROUND OF THE INVENTION

1. Field of the Invention

The present invention relates generally to a method of forming a semiconductor device, and more particularly to form a radio frequency (RF) inductor on a semiconductor substrate.

2. Description of the Prior Art

Monolithic inductors built on silicon substrates are widely used in CMOS based RF circuits such as low-noise amplifiers, voltage-controlled oscillators, and power amplifiers. Conventional inductors that are created on the surface of a substrate are of a spiral shape, wherein the spiral is created in a plane that is parallel with the plane of the surface of the substrate.

Aluminum metallization layers such as aluminum-copper (Al—Cu) alloys are typically used to form spirals of prior art inductors. The composition of Al—Cu alloys presently used for metallization inductors typically ranges from 99.5% aluminum-0.5% copper to 99.0% aluminum-1.0% copper, where the concentrations are listed as weight percentages.

As known in the art, one of the most important characteristics of the inductor is the quality factor Q, since it affects the performance of the RF circuits and systems. The quality factor of an integrated circuit is limited by parasitic losses within the substrate itself. These losses include high resistance through metal layers of the inductor itself. Consequently, in order to achieve a high quality factor, resistance within the inductor should be held to a minimum. One technique used to minimize the resistance within the inductor is increasing the thickness of metal used to fabricate the inductor.

However, problems arise when fabricating thick Al—Cu alloy film via conventional sputter deposition processes. The intermetallic compound residue “CuAl₂”, precipitates during deposition and co-exists with the aluminum rich “matrix” phase which forms the basis of the film. These CuAl₂ residues are more difficult to remove during reactive-ion-etching (“RIE”) processes, which are used to define and pattern the inductor. After the RIE process, the CuAl₂ residues often remain on the surface of the silicon wafer in regions, which should normally be cleared of any traces of the aluminum-copper film. These remaining CuAl₂ residues are identified as the source of decreased manufacturing yield during fabrication.

In light of the above, there is a need in this industry to provide an improved method of fabricating aluminum-copper alloy-based inductor for RF circuits, wherein the inductor is made of thicker aluminum-copper alloy film that is deposited via sputter deposition process, and wherein the phenomenon of CuAl₂ residue precipitation is alleviated or eliminated.

### SUMMARY OF THE INVENTION

Accordingly, the main object of this invention is to provide a method of forming an inductor device on a semiconductor substrate.

According to the claimed invention, a method of forming a semiconductor inductor having improved quality factor includes the steps of:

(a) loading a wafer into a physical vapor deposition (PVD) tool comprising a vacuum transfer chamber that couples to a pass-through chamber, a cool down chamber, an aluminum-copper sputter deposition process chamber, and an anti-reflection coating process chamber;

(b) sputter-depositing a first layer of aluminum-copper alloy onto the wafer in the aluminum-copper sputter deposition process chamber to a first thickness;

inter-cooling the wafer and the first layer of aluminum-copper alloy in the cool down chamber;

(c) sputter-depositing a second layer of aluminum-copper alloy onto the cooled down first layer of aluminum-copper alloy in the aluminum-copper sputter deposition process chamber to a second thickness;

(d) coating an anti-reflection film onto the second layer of aluminum-copper alloy in the anti-reflection coating process chamber at a relatively low temperature;

(e) cooling the wafer in the cool down chamber;

(f) un-loading the wafer from the PVD tool via the pass-through chamber; and

(g) etching the anti-reflection film, the first and second layers of aluminum-copper alloy deposited on the wafer into the semiconductor inductor using a reactive ion etching process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 depicts a schematic illustration of an apparatus that can be used for the practice of embodiments described herein; and

FIG. 2 is a flow chart showing the key steps of sputter depositing a thick aluminum-copper alloy film on a substrate according to the preferred embodiment of the present invention.

### DETAILED DESCRIPTION

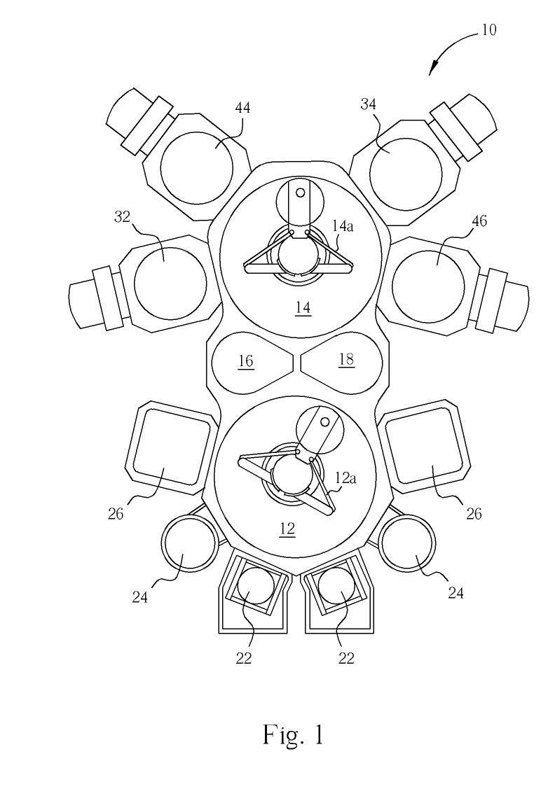

FIG. 1 is a schematic diagram showing the plan view of an exemplary wafer processing system 10 for sputter depositing a thick (>30,000 angstroms) aluminum-copper alloy film on a substrate according to this invention. An example of such a wafer processing system is an ENDURA System, commercially available from Applied Materials, Inc., Santa Clara, Calif.

The wafer processing system 10 includes a buffer chamber 12 and a transfer chamber 14 with respective wafer handler robots 12a and 14a positioned therein. A pass-through chamber 16 and a cool down chamber 18 are disposed between the buffer chamber 12 and transfer chamber 14. The buffer chamber 12 is separated from the transfer chamber 14 by the pass chamber 16 and cool down chamber 18.

The buffer chamber 12 is coupled to load-lock chambers 22, degas chambers 24, and expansion chambers 26. Substrates or wafers (not shown) are loaded into the wafer processing system 10 through the load-lock chambers 22. Thereafter, the substrates are sequentially degassed and cleaned in degas chambers 24 and the expansion chambers 26, respectively. The wafer handler robot 12a moves the substrate between the chambers 24 and 26.

The transfer chamber 14 is coupled to a cluster of process chambers 32, 34, 44, 46. The cleaned substrate is moved from the buffer chamber 12 into the transfer chamber 14 via the pass-through chamber 16. Thereafter, the wafer handler robot 14a moves the substrate between the process chambers 32, 34, 44, 46. According to this invention, the process chambers 32, 34, 44, 46 are PVD chambers, wherein the process chambers 32 and 34 are used to perform sputter deposition of aluminum-copper alloy, and the process chambers 44 and 46 are used to perform anti-reflective coating (ARC).

It is understood that process chambers 32, 34, 44, 46 may be used to perform other integrated circuit fabrication sequences including physical vapor deposition (PVD), ionized metal plasma physical vapor deposition (IMP PVD), chemical vapor deposition (CVD), and rapid thermal process (RTP), among others.

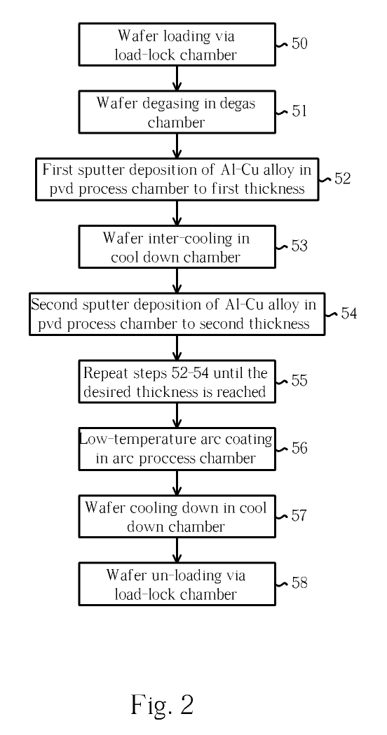

FIG. 2 is a flow chart showing the key steps of sputter depositing a thick aluminum-copper alloy film on a substrate according to the preferred embodiment of the present invention. Referring to FIG. 2, and briefly back to FIG. 1, a semiconductor wafer is first transferred into the load-lock chamber 22 (Step 50). After the wafer is placed in a vacuum environment, the wafer handler robot 12a moves the wafer to the next chamber, i.e., degas chamber 24. In the degas chamber 24, the wafer undergoes a degas process for pre-cleaning contaminations from a pre-layer process (Step 51).

After degassing, the wafer is then transferred to PVD chamber 32 via the pass-through chamber 16. In the PVD chamber 32, a first layer of Al or Al—Cu alloy is sputter-deposited onto the wafer surface (Step 52). During the deposition of the first layer of Al or Al—Cu alloy, the wafer temperature rises to about 400° C. In aluminum sputter PVD, a DC power source of about 9000-11000 Watts is provided and results in metal target with a negative bias and the wafer with a positive bias causing unidirectional plasma current from the wafer to the target. In another case, pulsed sputtering which is a DC sputtering process where the power source is pulsed may be employed.

Ionized target particles sputtered from the target is deposited onto the substrate to form the first layer of Al or Al—Cu alloy having a first thickness of 6000-10000 angstroms, for example, 8,000 angstroms. After reaching the first thickness, the sputter deposition process is paused. The wafer bearing the first layer of Al or Al—Cu alloy is immediately transferred into the cool down chamber 18. Once the wafer of high temperature is loaded into the cool down chamber 18, a flow of inert gas (cooling gas) such as argon, helium or nitrogen is flowed into the chamber 18 to cool down the wafer (Step 53).

According to the preferred embodiment of this invention, the cooling gas flows into the cool down chamber 18 at a flowrate of about 20-100 sccm for a time period of about 10-120 seconds. The wafer is cooled down to about 200-300° C.

After the inter-cooling, the wafer is transferred back to the PVD chamber 32 from the cool down chamber 18. A second stage of begins to deposit the second layer of Al or Al—Cu alloy onto the first layer (Step 54). According to this invention, the second layer of Al or Al—Cu alloy has substantially the same thickness as the first layer.

According to this invention, the steps 52-54 can be repeated until the desired thickness of the Al or Al—Cu alloy is reached (Step 55). By way of example, according to this invention, it may need five times sputter deposition (8,000 angstroms for each time) and four times inter-cooling steps in order to deposit a high-quality, thick aluminum-copper alloy film with a thickness of 40,000 angstroms.

After the deposition of the thick Al or Al—Cu alloy film is completed, the wafer is transferred to the process chamber 44 or 46 to carry out the deposition of anti-reflection coating (Step 56). According to this invention, a layer of titanium or titanium nitride (TiN) of about 500 angstroms is sputter deposited on the thick Al or Al—Cu alloy film at a relatively lower temperature of about 100-150° C. It has been found that the low-temperature anti-reflection coating process also helps to alleviate the copper precipitation of the underlying thick Al or Al—Cu alloy film.

After the low-temperature anti-reflection coating process, the wafer is transferred into the cool down chamber 18 and the wafer is cooled down therein (Step 57). Thereafter, the wafer is un-loaded via the load-lock chamber 22 (Step 58). The thick Al or Al—Cu alloy film on the wafer is then etched into a semiconductor inductor by using conventional lithographic and RIE processes, which are known in the art and the details are therefore omitted.

The present invention features the multi-stage Al—Cu alloy sputter deposition and inter-cooling step between two adjacent Al—Cu alloy sputter PVD steps. Since the wafer is constantly cooled down during the deposition of the thick film, a very high-quality Al—Cu alloy film is obtained. The copper precipitation of the deposited Al—Cu alloy film can be alleviated or eliminated.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a semiconductor inductor, comprising:
sputter-depositing a first layer of aluminum-copper alloy onto a wafer to a first thickness;
cooling the wafer and the first layer of aluminum-copper alloy in a cool down chamber;
sputter-depositing a second layer of aluminum-copper alloy onto the first layer of aluminum-copper alloy to a second thickness;
coating an anti-reflection film onto the second layer of aluminum-copper alloy at a relatively low temperature; and
etching the anti-reflection film, the first and second layers of aluminum-copper alloy into the semiconductor inductor.

2. The method according to claim 1 wherein the step of cooling the wafer and the first layer of aluminum-copper alloy in the cool down chamber includes the use of a flow of inert gas.

3. The method according to claim 2 wherein the inert gas includes argon, helium and nitrogen.

4. The method according to claim 1 wherein the wafer and the first layer of aluminum-copper alloy are cooled down to about 200-300° C. in the cooling step.

5. The method according to claim 1 wherein the first thickness is about 6000-10000 angstroms.

6. The method according to claim 1 wherein the second thickness is about 6000-10000 angstroms.

7. The method according to claim 1 wherein the relatively low temperature is about 100-150° C.

8. A method of forming a semiconductor inductor having improved quality factor, comprising:
loading a wafer into a physical vapor deposition (PVD) tool comprising a cool down chamber, an aluminum-copper sputter deposition process chamber, and an anti-reflection coating process chamber;
sputter-depositing a first layer of aluminum-copper alloy onto the wafer in the aluminum-copper sputter deposition process chamber to a first thickness;
inter-cooling the wafer and the first layer of aluminum-copper alloy in the cool down chamber;
sputter-depositing a second layer of aluminum-copper alloy onto the cooled down first layer of aluminum-copper alloy in the aluminum-copper sputter deposition process chamber to a second thickness;
coating an anti-reflection film onto the second layer of aluminum-copper alloy in the anti-reflection coating process chamber at a relatively low temperature; and
etching the anti-reflection film, the first and second layers of aluminum-copper alloy deposited on the wafer into the semiconductor inductor using a reactive ion etching process.

9. The method according to claim 8 wherein the step of inter-cooling the wafer and the first layer of aluminum-copper alloy in the cool down chamber includes the use of a flow of inert gas.

10. The method according to claim 9 wherein the inert gas includes argon, helium and nitrogen.

11. The method according to claim 8 wherein the wafer and the first layer of aluminum-copper alloy are cooled down to about 200-300° C. in the inter-cooling step.

12. The method according to claim 8 wherein the first thickness is about 6000-10000 angstroms.

13. The method according to claim 8 wherein the second thickness is about 6000-10000 angstroms.

14. The method according to claim 8 wherein the relatively low temperature for coating the anti-reflection film onto the second layer of aluminum-copper alloy is about 100-150° C.
